(19) United States
(12) Patent Application Publication
(10) Pub. No.: US 2026/0134910 A1
(43) Pub. Date: May 14, 2026

(54) DPIM SELF-TIMED LOCAL READ AND DYNAMIC STORAGE

(71) Applicants: AKHIL PAKALA, SANTA CLARA, CA (US); BALAJI VIJAYAKUMAR, HORAMAVU (IN); JOHN YU, SAN JOSE, CA (US); YUAN-JU CHAO, CUPERTINO, CA (US); KRISHNAMURTHY SUBRAMANIAN, SARATOGA, CA (US)

(72) Inventors: AKHIL PAKALA, SANTA CLARA, CA (US); BALAJI VIJAYAKUMAR, HORAMAVU (IN); JOHN YU, SAN JOSE, CA (US); YUAN-JU CHAO, CUPERTINO, CA (US); KRISHNAMURTHY SUBRAMANIAN, SARATOGA, CA (US)

(21) Appl. No.: 19/382,666

(22) Filed: Nov. 7, 2025

Related U.S. Application Data
(60) Provisional application No. 63/719,724, filed on Nov. 13, 2024.

(51) Int. Cl. G11C 11/419

(52) U.S. Cl. CPC G11C 11/419

(57) ABSTRACT

A digital processing-in-memory (DPIM) macro operates to perform memory readout and multiply-accumulate (MAC) computation in a cycle-constrained design. Access on a local bit-line through a self-timed circuit that integrates pre-charge and word-line enable is performed in a single clock cycle. Further, local bit-line parasitic capacitance is utilized for weight retention during multiple compute clock cycles. A high-skew inverter, operating as a local sense amplifier, further optimizes read access times with minimal area impact, enhancing access speeds. The DPIM macro can effectively handle 4/8-bit inputs with 1-bit weights over 5/9 cycles,

### FIELD OF THE INVENTION

The present disclosure relates to the operation of a static random-access memory (SRAM) cluster, and specifically to a method for single-cycle SRAM local read with dynamic storage for multiple bit digital processing in memory (PIM).

### BACKGROUND

Artificial intelligence (AI) applications are typically memory intensive, and are generally implemented with a convolutional neural network (CNN), such as the CNN represented in FIG. 1. For an AI application to operate efficiently, it is necessary to implement a fully connected neural network layer (see FIG. 2), having a comparatively large number of neurons which are comprised of, among other things, a plurality of static random-access memory (SRAM) cells. Further, in order to improve computational efficiency, in-memory computing (IMC) techniques have been designed to limit the movement of data between a compute function and memory. One in-memory computing architecture is a Charge-Domain In-Memory Computing 6T-SRAM (CAP-RAM), such as the one represented in FIG. 3. The design and operation of a CAP-RAM macro is described in a paper published by the IEEE in 2021 under the title “CAP-RAM: A Charge-Domain In-Memory Computing 6T-SRAM for Accurate and Precision-Programmable CNN Inference”.

Generally, each memory cell comprising a cluster can operate to maintain a weight value (either a logical one or zero) that is read-out from the cell prior to a multiply and accumulate (MAC) operation. Subsequently, the weight and an input vector value to the CNN are multiplied and further accumulated during the MAC process to create a point product used by a convolutional neural network for a variety of different reasons.

### BRIEF DESCRIPTION OF THE DRAWINGS

FIG. 1 is a diagram showing functional elements comprising a convolutional neural network.

FIG. 2 is a diagram illustrating connectivity of neurons comprising a fully connected portion of a CNN.

FIG. 3 is a diagram illustrating a compute in-memory arrangement comprising clusters of 6T SRAM memory cells.

FIG. 4 is a diagram illustrating one of the SRAM memory cell clusters in FIG. 3.

FIG. 5A is an SRAM self-timing circuit arrangement.

FIG. 5B is a diagram illustrating a time relationship between the signals in the self-timing circuit.

FIG. 6 is a diagram illustrating a pre-charging action with respect to the LBLB.

FIG. 7A is a diagram illustrating the relationship between a memory cell and an LBL and LBLB.

FIG. 7B is a diagram illustrating memory cell trigger timing.

FIG. 8A is a diagram illustrating memory cell activity after being triggered.

FIG. 8B is a timing diagram illustrating LBLB action as the result of the memory cell in FIG. 7A being triggered.

FIG. 9A is a diagram illustrating a relationship between a memory cell and a hi-skew inverter.

FIG. 9B is a diagram illustrates the timing relationship between the hi-skew inverter and the LBLB level.

FIG. 10A is a diagram illustrating KEEPER circuit activation when W=1.

FIG. 10B is a diagram illustration of a timing relationship among signals comprising the KEEPER circuit.

FIG. 11A is a diagram illustrating KEEPER circuit activation when W=0.

FIG. 11B is a diagram of the KEEPER circuit of FIG. 11A.

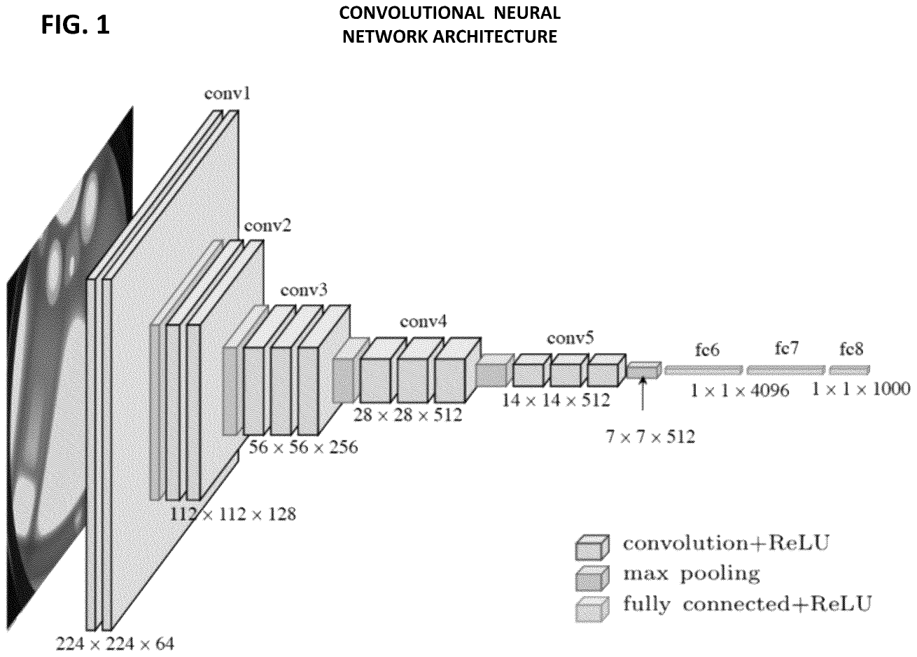

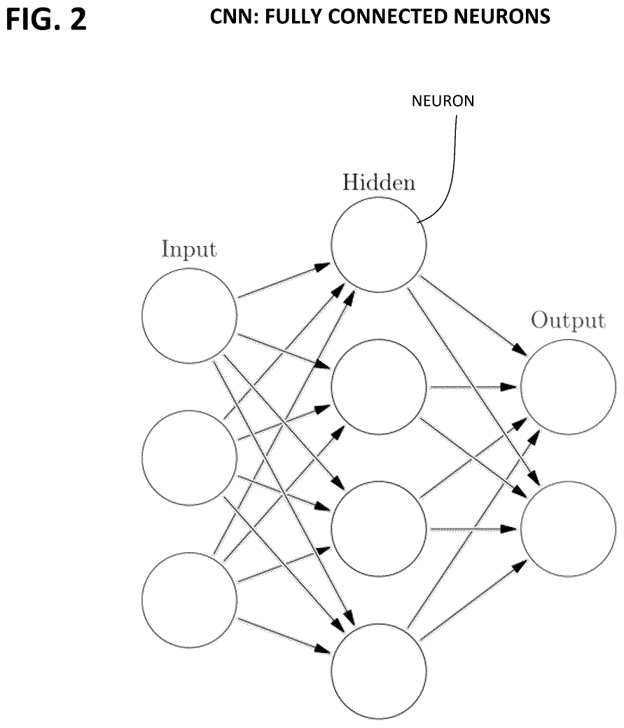

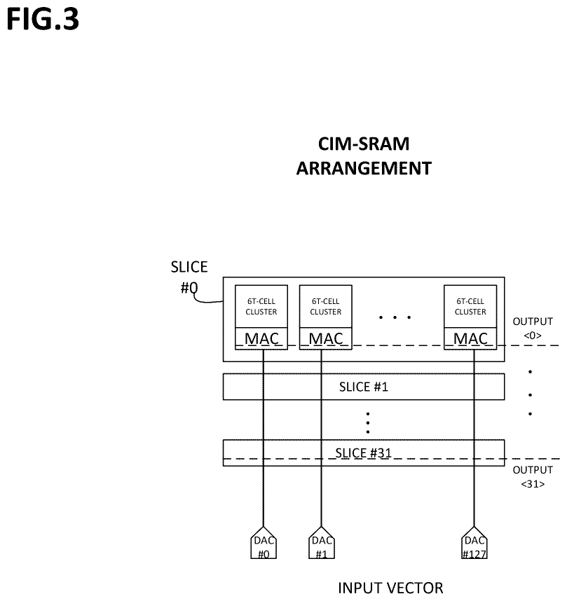

### DETAILED DESCRIPTION

In order to quickly readout weight information maintained in a memory cell, a local bit-line connected to the output of the memory cell is typically pre-charged to a particular voltage level. Subsequent to the bit-line being pre-charged, the weight information can be read, by a sensing amplifier, from the cell on the local bit-line. This two-step process for reading out the weight is generally performed in two sequential clock cycles, in which the first cycle is the pre-charge action, and a second cycle is the weight read-out action.

To improve the efficiency with which a CNN processes information, a digital processing-in-memory (DPIM) macro has been designed comprising SRAM circuit techniques that perform memory read-out and multiply-accumulate (MAC) computation in a cycle constrained design.

According to one embodiment, read access is enabled on a local bit-line by a self-timed circuit that integrates local bit-line pre-charge and word-line enable in a single clock cycle.

According to another embodiment, local bit-line parasitic capacitance is employed to retain weight information sensed during a read operation, wherein the weight information is retained for the duration of a MAC operation.

According to another embodiment, a pre-charge circuit and a high-skew inverter, operating as a sense amplifier, are optimally sized to perform both an LBLB pre-charging operation and a local readout operation within a single clock cycle.

The self-timed SRAM circuit macro design disclosed herein operates to effectively read and dynamically maintain one bit weights for five to eight clock cycles during a time that four-bit or eight-bit inputs are processed by the CNN during a MAC operation.

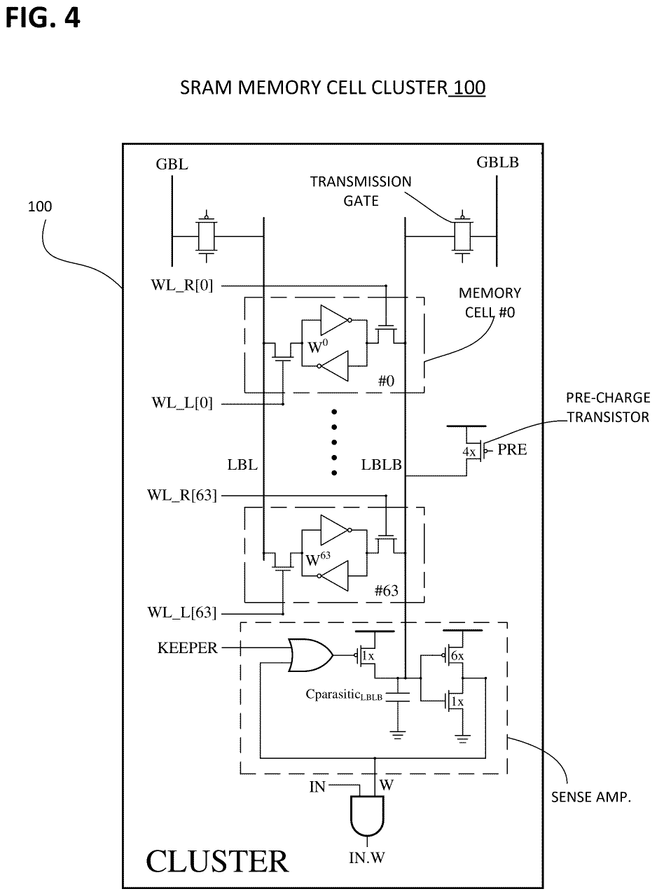

The above and other embodiments will now be described with reference to the figures, in which FIG. 4 is a circuit diagram illustrating a 6T SRAM memory cell cluster 100. The cluster is comprised of a plurality of memory cells, which in this case is 64 cells (cell #0-cell #63). Each cell is comprised of two pass transistors and two pairs of cross-coupled inverters, where each inverter is comprised of one NMOS and one PMOS transistor forming a latch that is controlled by the pass transistors to either receive a bit of weight information or to allow the weight information to be read. Each cell is connected to two word-lines WL_R and WL_L, and each cell is connected to two local bit-lines, LBL and LBLB, that are common to all of the memory cells comprising the cluster. Each word-line is connected to, and controls the operation of, the pass transistors to address each memory cell during a write and a read operation. The memory cell cluster 100 also has a hi-skew inverter circuit and a pre-charge circuit (transistor) both of which are connected to the LBLB. The hi-skew inverter operates as a sense amplifier to detect and amplify a voltage level on the LBLB during a read operation, and the pre-charge transistor operates, under control of a PRE signal, to charge the LBLB to Vdd during a pre-charge operation that occurs immediately prior to a read operation.

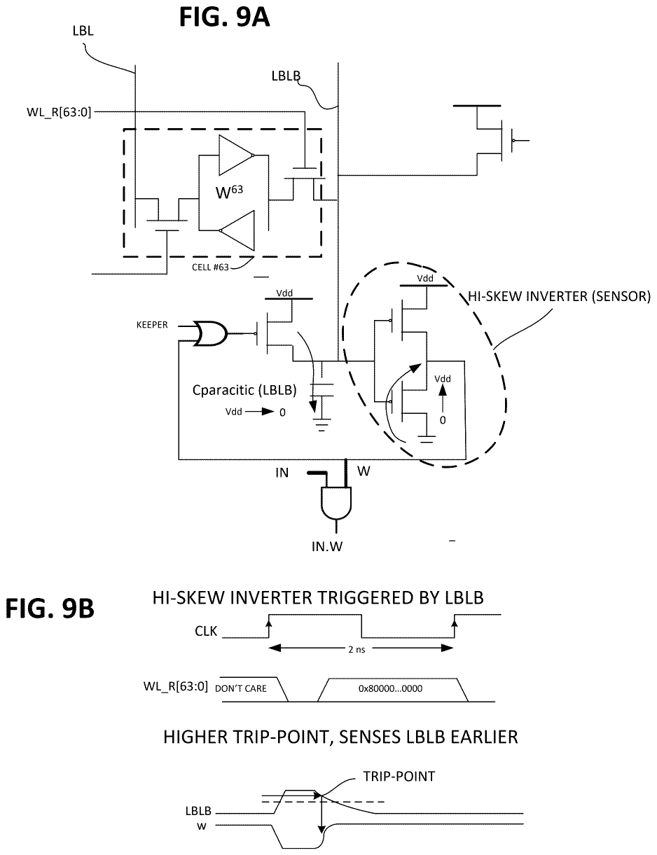

According to one embodiment, the pre-charge transistor and the sense amplifier are sized to perform both the pre-charge and the local-read operations within one clock cycle. Specifically, the pre-charge transistor is upsized by four times the unit size (i.e., Wmin & Lmin) which has the effect of accelerating the pre-charge phase. Also, because a logic “0” can be sensed when the LBLB level is above Vdd/2, the skewed inverter-based sense amplifier is designed to have a trip point that is between Vdd and Vdd/2, which is higher than the typical Vdd/2 trip point. As will be described later with reference to FIGS. 9A and 9B, this higher trip point allows the sensor to detect a logic “0” in less time than if the sensor trip point is set to Vdd/2.

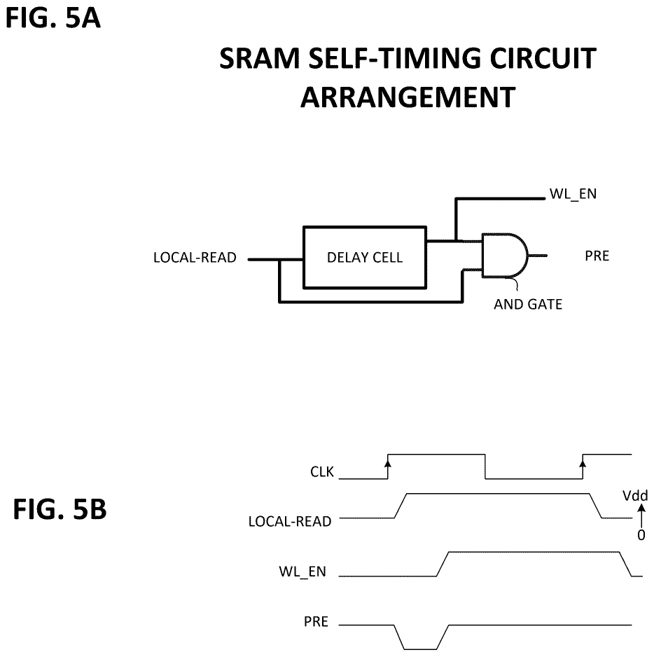

Referring now to FIGS. 5A and 5B. FIG. 5A is a diagram illustrating an SRAM self-timing circuit arrangement. This circuit is triggered by a LOCAL READ (LR) signal that is generated periodically at the end of a previous read operation. The LR signal is an input to both a delay cell and an AND gate. The output of the delay cell is another input to the AND gate and also serves as a word-line to enable (WL_EN) signal. The output of the AND gate is a pre-charge trigger signal (PRE) described earlier with reference to FIG. 4. FIG. 5B is a diagram illustrating the timing relationship between the LOCAL-READ, the PRE, and the WL_EN signals. As can be seen in FIG. 5B, the pre-charge operation completes prior to triggering the word-line. In operation, the LOCAL-READ signal triggers the self-timing circuit to generate the control signals, WL_EN and PRE, such that a timing relationship between these signals enables the pre-charging operation and a local-read operation to be completed within a single clock cycle. Further, the local read signal is maintained at a logical HI during the entire clock cycle, and the WL_EN signal goes to HI at the same time as the PRE signal.

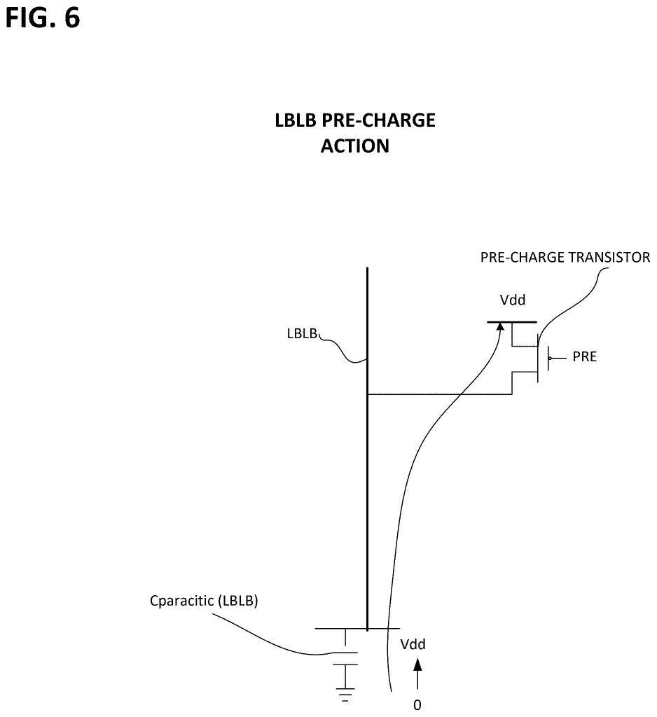

Referring now to FIG. 6, which is a diagram illustrating an LBLB pre-charge action that is triggered by the PRE signal received from the self-timing circuit described earlier. This figure shows a PMOS device, labeled pre-charge transistor, that receives the PRE signal from the delay circuit which triggers the pre-charge phase. During the pre-charge phase, the PMOS device pulls the LBLB up from a ground potential to Vdd. As described earlier, the pre-charge transistor is sized so that the pre-charge phase is accelerated and can be substantially completed within a one-quarter clock cycle. It should be understood that the period to pull the LBLB up from ground potential to Vdd can be shorter or longer depending upon the PMOS device size that is implemented. This design choice is constrained by, among other things. device space, power requirements, and operational speed.

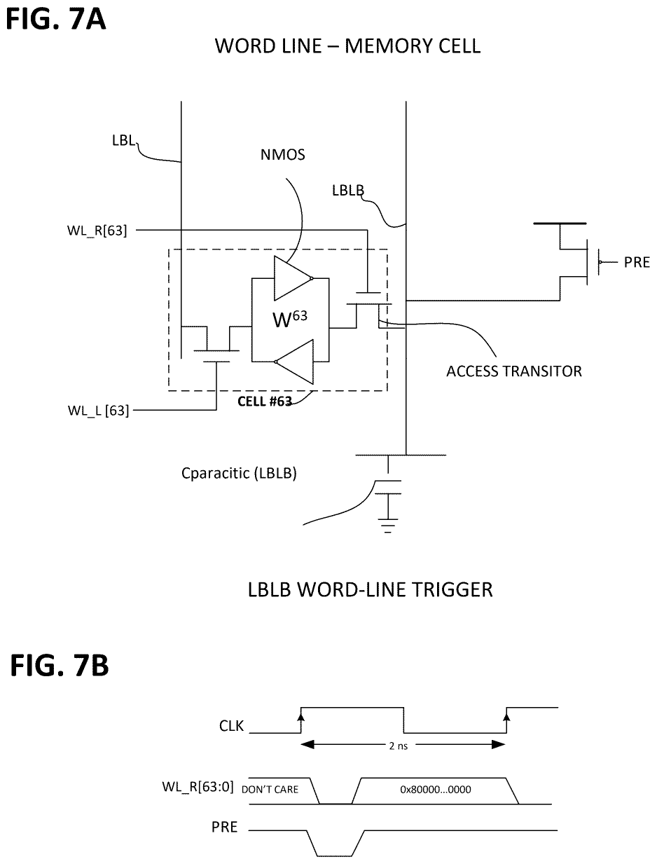

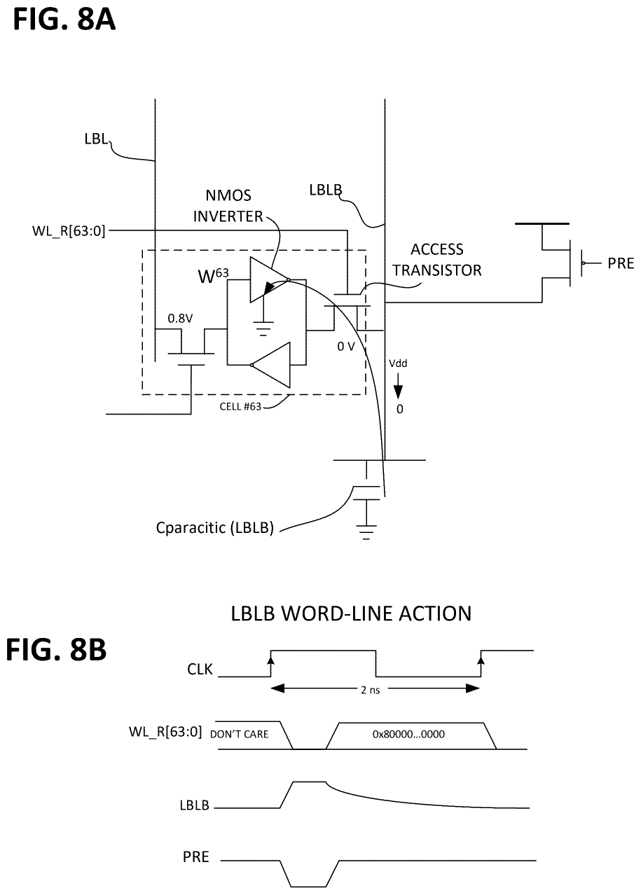

Referring now to FIGS. 7A and 7B. A memory cell labeled CELL #63 in FIG. 7A is comprised of the same components, and has the same connectivity to signal lines, as described earlier with reference to FIG. 4. As can be seen in FIG. 7A, the latch comprising the memory cell stores a weight that is labeled W⁶³. Prior to the word-line connected to the CELL #63 being enabled, the LBLB is pre-charged to Vdd. Subsequent to enabling the word-line and addressing a selected access transistor (FIG. 7B) to be turned on, one or the other (depending on the stored logic state) of the cross-coupled NMOS pairs operate to pull the LBLB from Vdd to ground over a period of time, as illustrated in FIG. 8B.

FIGS. 8A and 8B illustrate the memory cell #63 action subsequent to the word-line being triggered by the signal WL_R[63]. After the access transistor is turned on, the LBLB voltage level can be pulled to ground through the NMOS inverter. The timing of this action is illustrated in the FIG. 8B diagram. As shown in FIG. 8B, as soon as the access transistor is turned on, LBLB is pulled to ground over a period during which the voltage level on the LBLB is available to be detected by the sensing amplifier described earlier with reference to FIG. 4.

FIG. 9A illustrates, among other things, a single-ended, hi-skew inverter operating as a sensing amplifier. The inverter is designed to detect values on the LBLB in a range between Vdd and Vdd/2 (i.e., trip point is set between Vdd and Vdd/2). While a trip-point in a prior art sense amplifier is typically set at half the supply voltage (i.e., Vdd/2), the embodiment of a hi-skewed inverter design described herein is implemented with a trip-point higher than Vdd/2. However, as an input signal (LBLB level) is consistently transitioning from a high level (Vdd) to a lower value over time (i.e., always a falling signal), the hi-skewed inverter according to this embodiment is designed to have a trip point that is higher than Vdd/2 to ensure the reliable detection of this behavior. This configuration enables the inverter to efficiently detect a small voltage drop from Vdd.

As illustrated in FIG. 9B, setting the trip-point higher than Vdd/2 permits a logical “0” to be read out faster than if the trip point is set to Vdd/2. Setting a higher trip point ensures that the duration of the pre-charge phase plus the duration that the word-line is controlled to be ON does not take longer than one clock cycle.

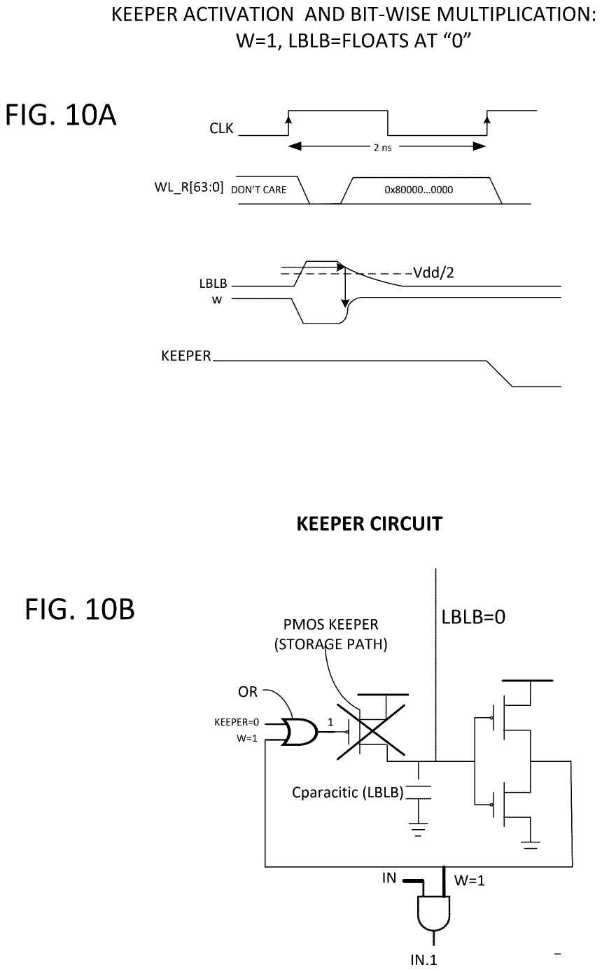

Subsequent to the sensor detecting and amplifying a voltage level read out on the LBLB, this level/weight (either a logical “1” or “0”), has to be maintained during a compute phase, which depending on the number of input bits can be either 4 or 8 clock cycles in addition to the pre-charge and read phases of the initial clock cycle. A keeper circuit, illustrated in FIG. 10B, is designed to maintain a logical “0” value using parasitic capacitance of the local bit-line bar (LBLB) during the time it takes to complete a multiply-and-accumulate operation. On the other hand, if the sensor detects a logical “1” the KEEPER PMOS device is not activated (i.e., W=1).

Continuing to refer to FIGS. 10A and 10B, the keeper circuit is activated by a KEEPER signal which is triggered to transition to a LO logic level subsequent to the word-line becoming inactive. A timing relationship between the WL_R[63] signal and the KEEPER signal is illustrated with reference to FIG. 10A. As illustrated in FIGS. 10A and 10B, the sense amplifier is shown to be detecting a logical “1” (i.e., W=1), after which the LBLB discharges from Vdd and floats at ground. As the sensor detects a logical “1” the output of the OR gate turns the PMOS keeper device off, preventing the weak keeper transistor from pulling LBLB HI, which in turn allows the LBLB to float to ground.

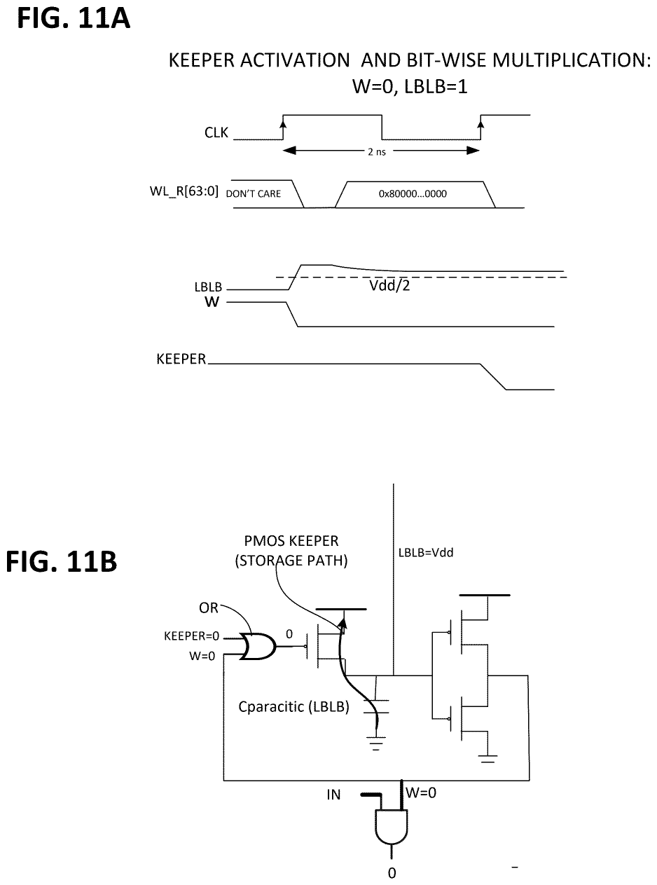

On the other hand, with reference to FIGS. 11A and 11B, if the sensor detects a logical “0” (i.e., W=0), the LBLB level is maintained at the pre-charged level during the MAC process. More specifically, sensing a logical “0” during the read operation causes the output of the OR gate to turn on the PMOS keeper device which pulls the parasitic capacitance of the LBLB up to Vdd.

The forgoing description, for purposes of explanation, used specific nomenclature to provide a thorough understanding of the invention. However, it will be apparent to one skilled in the art that specific details are not required to practice the invention. Thus, the forgoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications; they thereby enable others skilled in the art to best utilize the invention and various embodiments with various modifications as are suited to the particular use contemplated. It is intended that the following claims and their equivalents define the scope of the invention.

What is claimed is:

1. A self-timed SRAM cluster is controlled to complete both a local bit-line pre-charging and local bit-line read-out operation within one clock cycle, the self-timed SRAM cluster comprising:
a plurality of memory cells, with each memory cell being connected to the local bit line and a word line, and each memory cell is controlled to store a single bit of digital information that can be accessed on the local bit-line during the read-out operation;
wherein, at the beginning of a clock cycle a first signal (local read) initiates a self-timing circuit to generate second (pre-) and third (WL-EN) signals; and
wherein the second signal controls a pre-charge system to charge the local bit-line to Vdd prior to the third signal enabling the word line connected to the memory cell; and
wherein, subsequent to enabling the word line and addressing one of the plurality of the memory cells, a sensing amplifier connected to the local bit-line completes a local read operation prior to the end of the one clock cycle.
